(19) United States
(12) Patent Application Publication
(10) Pub. No.: US 2026/0297733 A1
(43) Pub. Date: Oct. 1, 2026

(54) LINER FOR BATCH SEMICONDUCTOR PROCESSING APPARATUS

(71) Applicant: ASM IP Holding B.V., Almere (NL)

(72) Inventors: Angelos Karagiannis, Alkmaar (NL); Theodorus G.M. Oosterlaken, Oudewater (NL); Herbert Terhorst, Amersfoort (NL); Lucian Jdira, Nieuw Vennep (NL); Subir Parui, Leuven (BE); Kelly Houben, Lubbeek (BE); Bert Jongbloed, Oud-Heverlee (BE)

(21) Appl. No.: 19/629,292

(22) Filed: Mar. 26, 2026

(30) Foreign Application Priority Data
Mar. 31, 2025 (GR) 20250100251

(51) Int. Cl. C23C 16/44; C23C 16/455; H10P 72/00; H10P 72/10

(52) U.S. Cl. CPC C23C 16/4404; C23C 16/4412; C23C 16/45578; H10P 72/0402; H10P 72/0434; H10P 72/12

(57) ABSTRACT

A liner for a process chamber of a batch semiconductor processing apparatus is disclosed. The liner comprises a closed upper end; an open lower end adapted for receiving a substrate boat; and a plurality of exhaust openings in the liner, distributed between the upper end and the lower end. The liner has a first diameter in a first liner section adjacent to the upper end and a second diameter in a second liner section adjacent to the lower end. The liner diameter increases continuously from the first diameter to the second diameter in a transition section between the first section and the second section.

### CROSS-REFERENCE TO RELATED APPLICATIONS

This application claims priority to Greek Patent Application Serial No. 20250100251 filed Mar. 31, 2025 and titled LINER FOR BATCH SEMICONDUCTOR PROCESSING APPARATUS, the disclosure of which is hereby incorporated by reference in its entirety.

### FIELD

The present disclosure relates generally to the field of semiconductor processing methods, and associated structures and apparatus, and to the field of device and integrated circuit manufacture. More particularly the present disclosure generally relates to a liner and an injector for use in a batch semiconductor processing apparatus.

### BACKGROUND

Vertical furnace systems are widely used in the semiconductor industry for batch processing of substrates, such as wafers, during various fabrication steps, including oxidation, diffusion, and chemical vapor deposition. These systems typically consist of a vertically oriented process chamber, a heating element, and a substrate boat that holds multiple substrates in a stacked arrangement. The substrates are processed simultaneously, allowing for efficient and uniform treatment.

A critical component of many vertical furnace systems is the liner, which is an inner housing, generally in the form of a tube with one open end and one closed end, placed within the process chamber. The liner serves several important functions that enhance the performance and longevity of the furnace system. One of the primary advantages of using a liner is its ability to protect the process chamber walls from corrosive gases and by-products generated during processing. This protection helps to extend the life of the furnace and reduce maintenance costs.

The liner also plays a role in managing gas flow within the chamber. Exhaust openings in the liner can facilitate the efficient removal of process gases and by-products, minimizing contamination and ensuring a clean processing environment. This gas management capability is important for achieving high-quality deposition and etching processes.

Furthermore, the use of a liner can simplify the cleaning and maintenance of the furnace system. Since the liner is a removable component, it can be easily replaced or cleaned without the need to disassemble the entire furnace. This feature reduces downtime and enhances the overall productivity of the semiconductor fabrication process.

In summary, the incorporation of a liner in a vertical furnace system offers several advantages, which contribute to the reliable and efficient operation of the furnace, making it an important component in modern semiconductor manufacturing.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

According to a first aspect of the present invention, there is provided a liner for a process chamber of a batch semiconductor processing apparatus. The liner comprises a closed upper end; an open lower end adapted for receiving a substrate boat; and a plurality of exhaust openings in the liner, distributed between the upper end and the lower end. The liner has a first diameter in a first liner section adjacent to the upper end and a second diameter in a second liner section adjacent to the lower end. The liner diameter increases continuously from the first diameter to the second diameter in a transition section between the first section and the second section.

The transition section may have a height of at least 30 mm.

The first liner section may have a height of at least three times a height of the second liner section.

The second diameter may be at least 1.1 times the first diameter.

The plurality of exhaust openings may include at least one opening in the transition section.

The plurality of exhaust openings may include at least one opening in the second liner section.

The plurality of exhaust openings may comprise a plurality of holes.

The plurality of exhaust openings may comprise a plurality of slits, each slit extending in a circumferential direction.

The plurality of exhaust openings may comprise a first series of openings located at a first circumferential position and spaced apart along a longitudinal axis of the liner, and a second series of openings located at a second, different circumferential position and spaced apart along a longitudinal axis of the liner.

The liner may comprise a first bulge extending along the longitudinal axis and located between the first series of openings and the second series of openings.

The liner may comprise a hole in the upper end of the liner at a top end of the first bulge.

The liner may comprise a second bulge extending along a longitudinal axis of the liner, located substantially diametrically opposite to the first bulge.

The liner may comprise a hole in the upper end of the liner at a top end of the second bulge.

According to a second aspect of the present invention there is provided an assembly of the liner according to the first aspect and a gas injector receivable in the second bulge. The gas injector comprises a lower injector end and an upper injector end; an injector wall extending between the lower injector end and the upper injector end and defining a gas conduit; and a series of holes in the injector wall spaced apart between the lower injector end and the upper injector end. The injector wall comprises a bend configured to allow the injector to conform to a shape of the liner when the injector is accommodated in the second bulge of the liner.

The bend may be an S-shaped bend.

The bend may be provided between a lowest of the series of holes and the lower injector end.

No holes may be provided in the injector wall at a position of the bend.

The gas conduit may have a circular cross-section in a plane perpendicular to the longitudinal axis of the liner.

The holes in the injector wall may be positioned so as to allow gas to flow out from the gas conduit through the holes in a direction which is substantially tangential to the liner in a plane perpendicular to the longitudinal axis of the liner.

The holes in the injector wall may be positioned so as to allow gas to flow out from the gas conduit through the holes in a direction which is substantially perpendicular to the liner in a plane perpendicular to the longitudinal axis of the liner.

The injector may comprise a plurality of projections at the upper injector end.

The assembly may comprise a cap configured to close off a hole in the upper end of the liner at a top end of the second bulge.

Other technical features may be readily apparent to one skilled in the art from the following figures, descriptions, and claims.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

Certain embodiments of the present invention will now be described, by way of example, with reference to the accompanying drawings, in which:

FIG. 1 is a perspective view of a liner according to embodiments of the present invention, illustrating the different sections of the liner;

FIG. 2 is a cross-sectional view of the liner of FIG. 1 through a plane A-A;

FIG. 3 is a perspective view of a liner according to embodiments of the present invention having a series of exhaust openings which are holes and are positioned in an alternating arrangement;

FIG. 4 is a perspective view of a liner according to embodiments of the present invention having a series of exhaust openings which are slits;

FIG. 5 is a perspective view of a liner according to embodiments of the present invention comprising bulges for accommodating components, viewed towards the hole-shaped exhaust openings;

FIG. 6 is a perspective view of the liner of FIG. 5, viewed from an opposite side;

FIG. 7 is a cross-sectional view of the liner of FIG. 5, taken in a plane perpendicular to the longitudinal direction and including line B-B;

FIG. 8 is a perspective view of a liner according to embodiments of the present invention comprising bulges for accommodating components, viewed towards the slit-shaped exhaust openings;

FIG. 9 is a perspective view of a top end of a liner according to embodiments of the present invention which comprises through holes at the top of the bulges;

FIG. 10 is a perspective view of a top end of the liner of FIG. 9 which comprises caps covering the through holes at the top of the bulges;

FIG. 11 is a perspective view of a liner according to embodiments of the present invention which has a taper at the upper end;

FIG. 12 is a cross-sectional view of the liner of FIG. 11 in a vertical plane;

FIG. 13 is a perspective view of an injector which may be provided with a liner in an assembly of an injector and a liner according to embodiments of the present invention;

FIG. 14 is a cross-sectional view of a batch semiconductor processing apparatus comprising an assembly of an injector and a liner according to embodiments of the present invention.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

Where in the present disclosure two or more elements are referred to as being “in fluid communication”, it is meant that a fluid such as a gas or liquid or mixture thereof can flow between the elements, in one or both directions. The fluid communication may be achieved, for example, by means of a gas line, tube, pipe, inlet, outlet, or any combination thereof. The fluid communication may be interruptible; for example, a valve or other flow control element may be present.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments. In some cases, percentages indicate herein can be relative or absolute percentages.

A number of example materials are given throughout the embodiments of the current disclosure, it should be noted that the chemical formulas given for each of the example materials should not be construed as limiting and that the non-limiting example materials given should not be limited by a given example stoichiometry.

In the specification, it will be understood that the term “on” or “over” may be used to describe a relative location relationship. Another element, film or layer may be directly on a mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

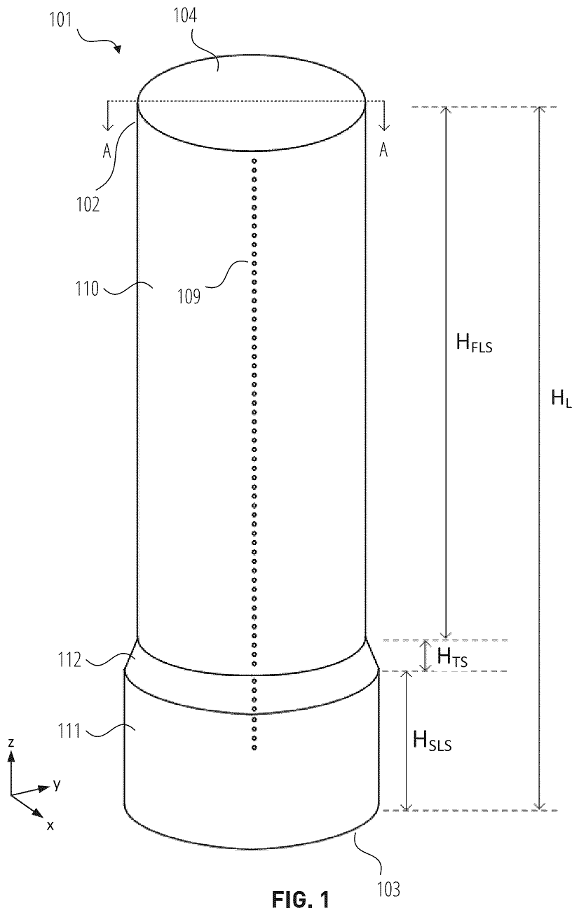

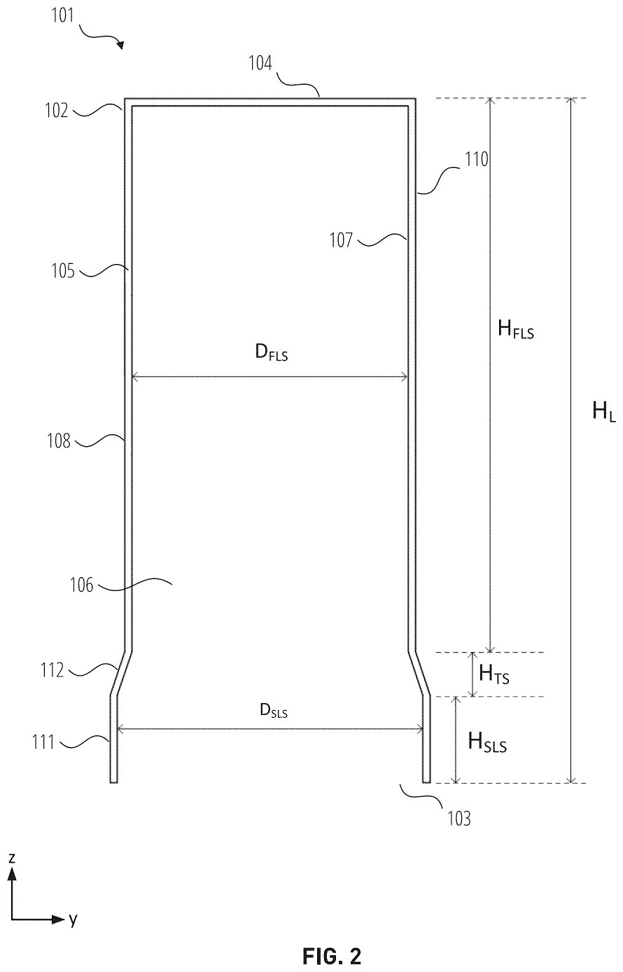

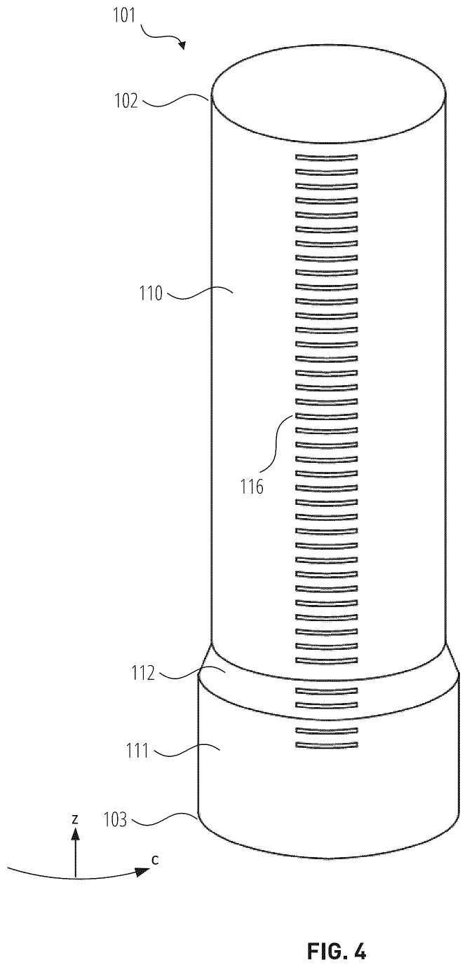

Referring to FIG. 1 and FIG. 2, a liner 101 according to embodiments of the present invention is shown. The liner 101 is generally cylindrical and comprises an upper end 102 which is closed and a lower end 103 which is open. The upper end 102 and the lower end 103 are spaced apart along a longitudinal direction z in which the liner 101 extends. The upper end 102 is closed by a top member 104. A liner wall 105 extends from the top member 104 to the lower end 103. The liner 101 has an inner volume 106 into which a substrate boat may be inserted via the lower end 103. The liner 101 has an inner surface 107, which faces the inner volume 106, and an outer surface 108, which faces away from the inner volume 106. A circumferential direction C (FIG. 4) may be defined as a direction in a plane perpendicular to the longitudinal direction around the inner surface 107 or outer surface 108.

The liner 101 comprises a plurality of openings 109 in the liner wall 105 which each connect the inner surface 107 with the outer surface 108. The plurality of openings 109 are spaced apart along the longitudinal direction and are distributed between the upper end 102 and the lower end 103. The openings 109 provide an exhaust path for gas from the inner volume 106 of the liner 101. The openings 109 may comprise, for example, holes or slits. The openings 109 may comprise between 50 and 400, between 100 and 300, between 150 and 250 openings 109.

The liner 101 comprises a first liner section 110 which is adjacent to the upper end 102, a second liner section 111 which is adjacent to the lower end 103, and a transition section 112 which is located between the first liner section 110 and the second liner section 111. That is, in a direction from the lower end 103 to the upper end 102, the liner 101 comprises first the second liner section 111, then the transition section 112, then the first liner section 110. The first liner section 110, the transition section 112, and the second liner section 111 do not overlap with each other in the longitudinal direction.

The liner 101 has a diameter D which may vary depending on position in the longitudinal direction. The liner 101 diameter D is measured between diametrically opposite points on the inner surface 107 in a plane perpendicular to the longitudinal direction. As will be described in more detail hereinafter, in some embodiments, the liner 101 may comprise a bulge. The liner diameter is measured at points which do not coincide with a bulge.

The liner 101 has a first liner diameter D_{FLS} in the first liner section 110, and a second liner diameter D_{SLS} in the second liner section 111. The second liner diameter is greater than the first liner diameter. In some embodiments, the second liner diameter may be at least 1.04 times the first liner diameter. In some embodiments, the second liner diameter may be at least 1.1 times the first liner diameter. In some embodiments, the second liner diameter may be at least 1.15 times the first liner diameter. The diameter of the liner 101 increases from the first diameter to the second diameter in the transition section 112. Thus the transition section 112 has a diameter equal to the first liner diameter at a boundary between the transition section 112 and the first liner section 110, and has a diameter equal to the second liner diameter at a boundary between the transition section 112 and the second liner section 111. The diameter increase is continuous. In other words, the diameter increase is not a step change in diameter. This provides a tapered profile for the inner surface 107 of the liner 101. The liner diameter may increase continuously over a full height H_{TS} of the transition section 112 in the longitudinal direction.

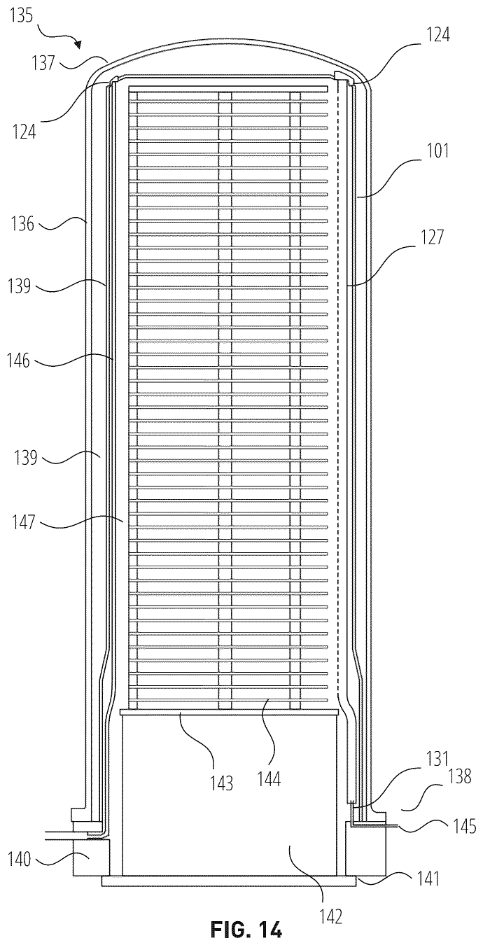

By providing a liner 101 with a first liner section 110 having a smaller diameter than the second liner section 111, the liner 101 can be made to conform more closely to a shape of a boat to be received in the liner 101, while still allowing space for a pedestal of a larger diameter than the supported in the boat, at the lower end 103 of the liner 101. This allows for an annular volume 147 (FIG. 14) between the liner and the wafers to be reduced. This may help to improve within wafer uniformity for deposition processes carried out in a semiconductor processing apparatus comprising the liner 101 according to embodiments of the present invention. This may also help to reduce precursor consumption by allowing a greater quantity of precursor to be forced between the wafers for deposition on the wafers, as compared to an amount of precursor flowing in the annular volume.

By providing a tapered transition between the smaller diameter first liner section 110 and the larger diameter second liner section, manufacturability of the liner 101 may be improved, for example as compared with a step change transition. A tapered transition may also help to reduce turbulent gas flow, for example as compared with a step change transition.

The liner 101 has a height H_{L} in the longitudinal direction. The transition section 112 may have a height H_{TS} in the longitudinal direction which is at least 30 mm and no more than 100 mm. The height H_{TS} of the transition section 112 may be at least 40 mm and no more than 60 mm. The first liner section 110 may have a height H_{FLS} in the longitudinal direction which is at least 1.5 times, for example 1.5 times, 2 times, 2.5 times, or 3 times a height H_{SLS} of the second liner section 111 in the longitudinal direction. The height H_{FLS} of the first liner section 110 may be at least 600 mm, at least 700 mm, or at least 800 mm. The height H_{FLS} of the first liner section 110 may be less than 1000 mm. The height H_{FLS} of the first liner section 110 may include a height of a tapered part of the first liner section 110 at the upper end 102 (FIG. 11). The height H_{SLS} of the second liner section 111 may be at least 100 mm, at least 150 mm, or at least 200 mm. The height H_{SLS} of the second liner section 111 may be less than 300 mm. In some embodiments, the height H_{FLS} of the first liner section 110 may be substantially the same as the height H_{SLS} of the second liner section 111. In some embodiments, the height H_{FLS} of the first liner section 110 may be between 1 times and 1.5 times or between 1 times and 2 times the height H_{SLS} of the second liner section 111.

The first liner diameter may be constant over the height of the first liner section 110. The second liner diameter may be constant over the height of the second liner section 111. The only change in diameter between the first liner section 110 and the second liner section 111 may take place in the transition section 112.

The plurality of openings 109 may comprise at least one opening in the transition section 112. The plurality of openings 109 may comprise at least one opening in the second liner section 111. By including openings in the transition section 112 and/or the second liner section 111, a gas flow towards the lower end 103 of the liner 101 may be improved, which can help to prevent stagnant flow at the lower end 103 of the liner 101 which can result in precursor decomposition and poor deposition performance at wafers situated towards the lower end 103.

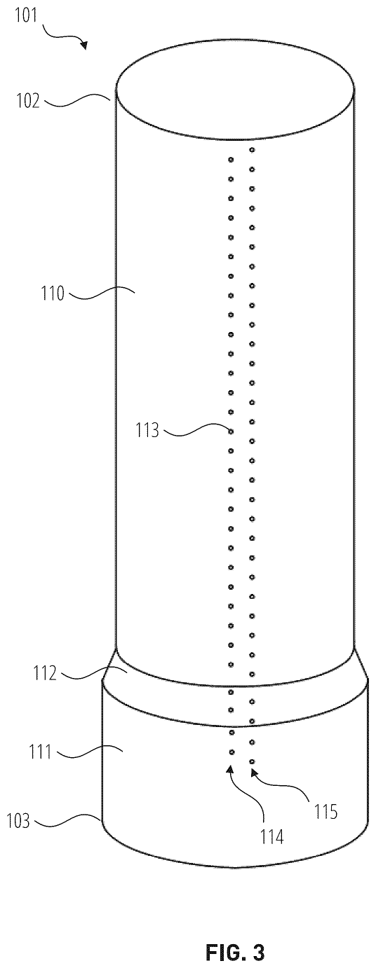

The plurality of openings may comprise a plurality of holes 113. The holes 113 may be generally circular shaped. The holes 113 may be provided as a single column of holes as shown in FIG. 1. Alternatively, referring to FIG. 3, the holes 113 may comprise a first series of holes 114 located at a first circumferential position and spaced apart along a longitudinal axis of the liner 101, and a second series of holes 115 located at a second, different circumferential position and spaced apart along a longitudinal axis of the liner 101. The holes in first series of holes 114 each have a different position along the longitudinal axis. The holes in the second series of holes 115 each have a different position along the longitudinal axis, each of these positions being different to the positions of the holes in the first series of holes 114. The holes may be positioned in an alternating configuration, that is, moving along the longitudinal direction, first a hole in the first series of holes 114 is provided, then a hole in the second series of holes 115, then a hole in the first series of holes 114 is provided, then a hole in the second series of holes 115, and so on. In some embodiments, each hole in the second series of holes 115 may have a same position along the longitudinal axis as one corresponding hole in the first series of holes 114. Thus each hole in a pair of holes having the same longitudinal position may be separated in the circumferential direction.

The plurality of openings may comprise a plurality of holes 113. The holes 113 may be generally circular shaped. The holes 113 may be provided as a single column of holes as shown in FIG. 1. Alternatively, referring to FIG. 3, the holes 113 may comprise a first series of holes 114 located at a first circumferential position and spaced apart along a longitudinal axis of the liner 101, and a second series of holes 115 located at a second, different circumferential position and spaced apart along a longitudinal axis of the liner 101. The holes in first series of holes 114 each have a different position along the longitudinal axis. The holes in the second series of holes 115 each have a different position along the longitudinal axis, each of these positions being different to the positions of the holes in the first series of holes 114. The holes may be positioned in an alternating configuration, that is, moving along the longitudinal direction, first a hole in the first series of holes 114 is provided, then a hole in the second series of holes 115, then a hole in the first series of holes 114 is provided, then a hole in the second series of holes 115, and so on. In some embodiments, each hole in the second series of holes 115 may have a same position along the longitudinal axis as one corresponding hole in the first series of holes 114. Thus each hole in a pair of holes having the same longitudinal position may be separated in the circumferential direction.

Referring to FIG. 4, the plurality of openings 109 may comprise a plurality of slits 116 spaced apart in the longitudinal direction. The slits 116 each extend in a circumferential direction C around the liner 101. The slits 116 may each have a same length in the circumferential direction. The slits 116 may have a length in the circumferential direction which is between 10% and 40% of the circumference of the liner at the longitudinal position of that slit. The slits 116 may each have a height in the longitudinal direction of less than 5 mm, less than 4 mm, less than 3 mm, less than 2 mm, or less than 1 mm. The slits 116 may be aligned such that each is located at a same circumferential position, that is, the slits 116 may be spaced apart only in the longitudinal direction and not in the circumferential direction.

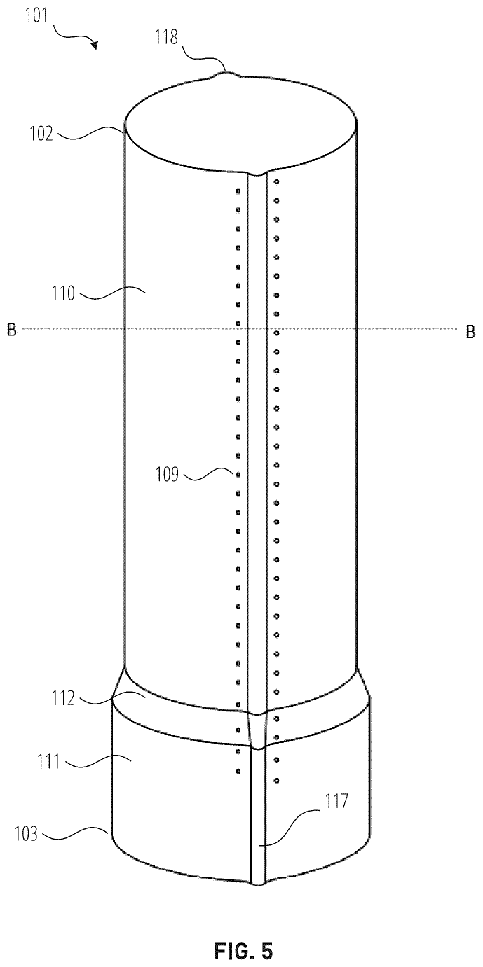

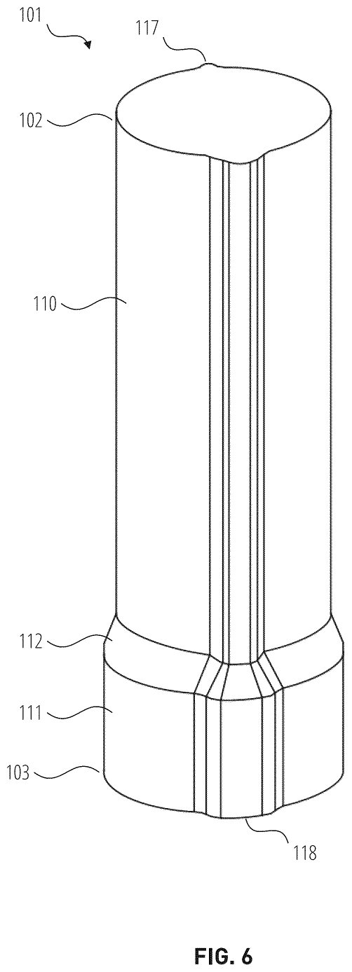

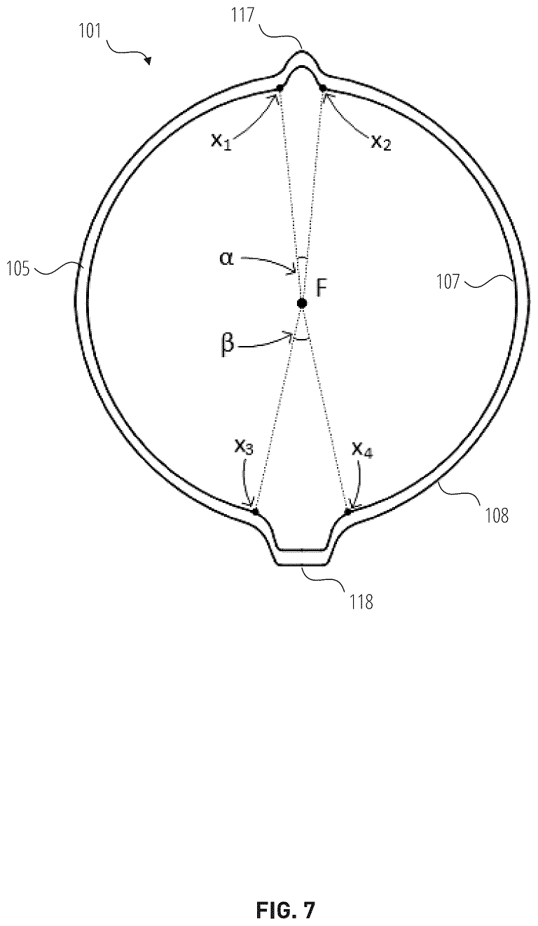

Referring to FIG. 5, FIG. 6, and FIG. 7, in some embodiments, the liner 101 comprises a first bulge 117, being a longitudinal section of the liner 101 which protrudes outwards such that the liner diameter is greater at the position of the first bulge 117 than away from the first bulge 117. The first bulge 117 may extend from the upper end 102 to the lower end 103 and may therefore be present in the first liner section 110, the second liner section 111, and the transition section 112. The first bulge 117 may be configured to accommodate a thermocouple (not shown) for measuring a temperature in the inner volume 106.

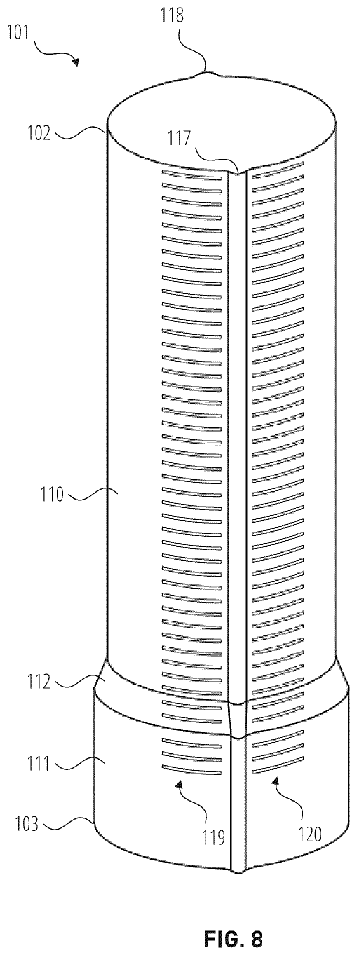

The plurality of openings 109 may be positioned on either side of the first bulge 117. For example, in some embodiments, the plurality of openings 109 comprises a first series of holes 114 and a second series of holes 115 and the first bulge 117 may be positioned between the first series of holes 114 and the second series of holes 115 in the circumferential direction C. In some embodiments, referring to FIG. 8, the plurality of openings 109 comprises a first series of slits 119 and a second series of slits 120 and the first bulge 117 may be positioned between the first series of slits 119 and the second series of slits 120 in the circumferential direction C. The first series of slits 119 may be located at a first circumferential position and spaced apart along the longitudinal axis of the liner 101, and the second series of slits 120 may be located at a second circumferential position different to the first circumferential position and spaced apart along a longitudinal axis of the liner 101.

The liner 101 may comprise a second bulge 118, being a longitudinal section of the liner 101 which protrudes outwards such that the liner diameter is greater at the position of the second bulge 118 than away from the second bulge 118. The second bulge 118 may extend from the upper end 102 to the lower end 103 and may therefore be present in the first liner section 110, the second liner section 111, and the transition section 112. The second bulge 118 may be located at a circumferential position which is diametrically opposite to that of the first bulge 117. The second bulge 118 may be configured to accommodate a gas injector (not shown) for providing gas to the inner volume 106. By providing the first bulge 117 and/or the second bulge 118, space may be provided for a thermocouple and/or injector inside the liner 101 without the need to increase the diameter of the liner 101 at all circumferential positions. This may allow for an annular volume 147 (FIG. 14) around a boat of substrates which may be placed in the inner volume 106 to be minimized while still providing space required for components to be provided inside the liner 101.

The first bulge 117 may subtend an angle α at a central longitudinal axis F of the liner 101 which is between 5 degrees and 25 degrees, or between 10 degrees and 20 degrees. The angle alpha may be measured as the angle subtended by two points x₁, x₂ on the liner on either side of the first bulge 117, being the points at which the diameter of the liner starts to increase to form the first bulge 117. The axis F is an axis which is parallel to the longitudinal direction and which is intersected by a diameter of the liner 101.

The second bulge 118 may subtend an angle β at a central longitudinal axis F of the liner 101 which is between 10 degrees and 60 degrees, or between 20 degrees and 40 degrees. The angle beta may be measured as the angle subtended by two points x₃, x₄ on the liner on either side of the second bulge 118, being the points at which the diameter of the liner starts to increase to form the second bulge 118.

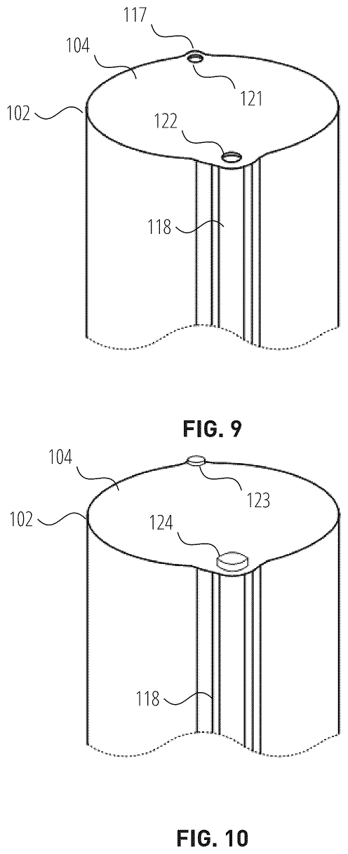

Referring to FIG. 9, the liner 101 may comprise a first through hole 121 at the upper end 102 at a top end of the first bulge 117. The first through hole 121 may be formed in the top member 104. The liner 101 may comprise a second through hole 122 at the upper end 102 at a top end of the second bulge 118. The second through hole 122 may be formed in the top member 104.

The first through hole 121 is sized so as to allow at least a top part of a component to be provided in the first bulge 117 to pass through the first through hole 121. This may help to provide a greater range of movement of a component in the longitudinal direction so as to improve a process of fitting, removal, or replacement of the component. The second through hole 122 is sized so as to allow at least a top part of a component to be provided in the second bulge 118 to pass through the second through hole 122. This may help to provide a greater range of movement of a component in the longitudinal direction so as to improve a process of fitting, removal, or replacement of the component. The first through hole 121 may have a diameter of between 5 mm and 30 mm, preferably between 10 mm and 20 mm. The second through hole 122 may have a diameter of between 10 mm and 40 mm, preferably, between 20 mm and 30 mm.

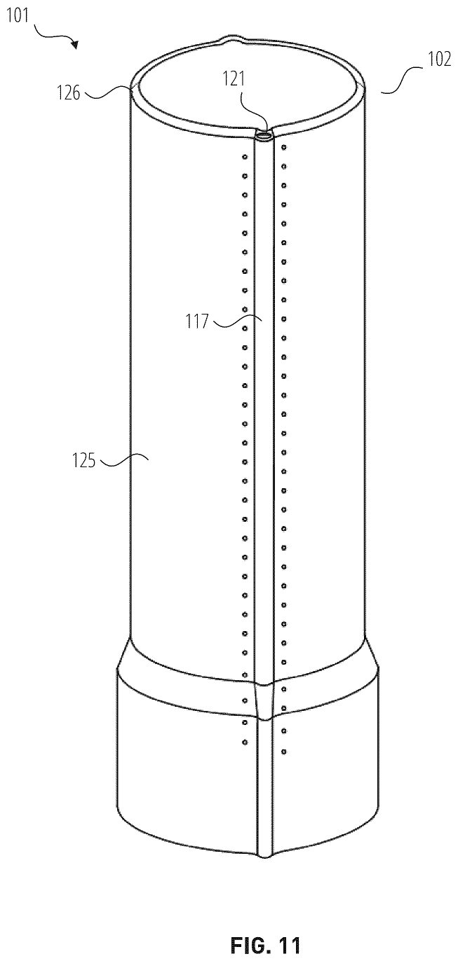

Referring to FIG. 10, the liner 101 may comprise a first cap configured to close off the first through hole 121 and a second cap configured to close off the second through hole 122. The caps may allow for the upper end 102 of the liner 101 to be substantially closed for gases while the top member 104 comprises the first through hole 121 and the second through hole 122.

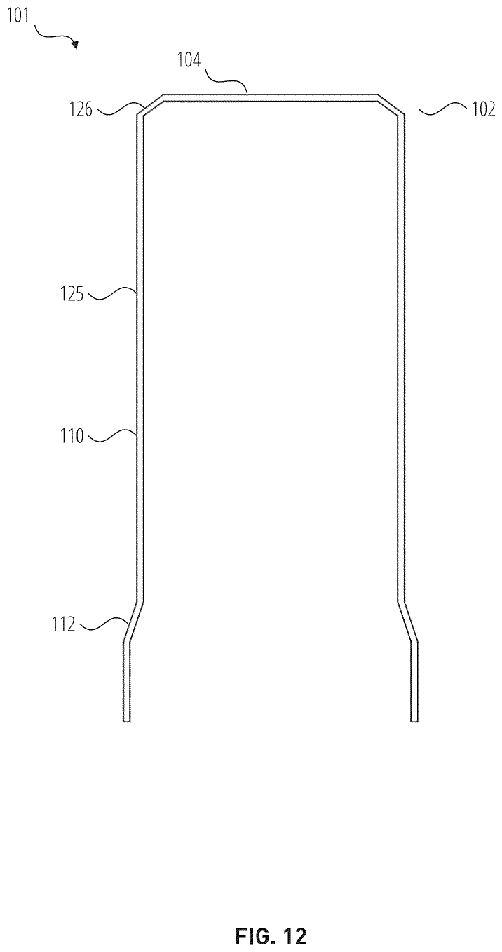

Referring to FIG. 11 and FIG. 12, in some embodiments, the upper end 102 may be tapered. The diameter of the first liner section 110 may be constant in a first part 125 of the first liner section 110 which is adjacent to the transition section 112 and may decrease in a second part 126 of the first liner section 110 which is adjacent to the upper end 102. The first part 125 is between the second part 126 and the transition section 112 in the longitudinal direction. The first through hole 121 and the second through hole 122 may be provided in the tapered second part 126. By providing a taper at the upper end 102, the height of the liner 101 may be increased, as the taper may allow for the liner to more closely conform to a domed shape of a top end of a process chamber.

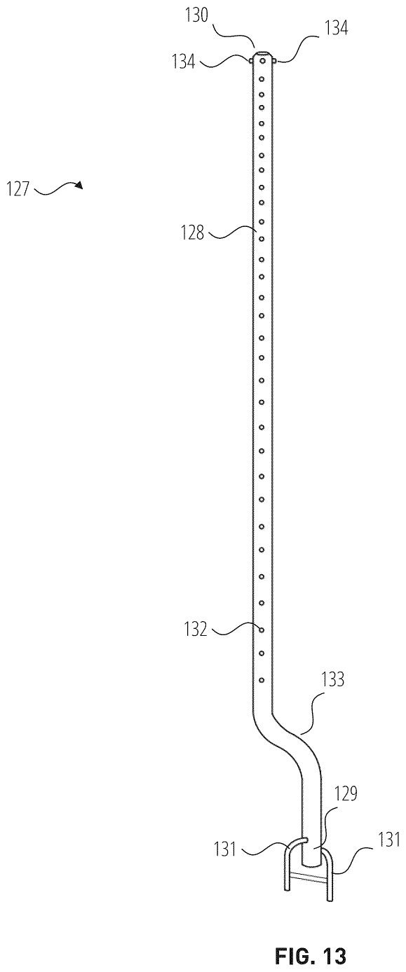

Referring to FIG. 13, an injector 127 is shown which may be provided together with a liner 101 according to embodiments of the present invention as an assembly of a liner and an injector. The injector 127 is generally tube shaped and comprises an injector wall 128 extending between a lower injector end 129 and an upper injector end 130. The injector wall 128 defines a gas conduit which may have a circular shape in a plane perpendicular to the longitudinal direction. The upper injector end 130 is closed. At the lower injector end 129, one or more gas inputs 131 may be provided. Each gas input 131 may be individually connected to a source of, for example, a process gas, a cleaning gas, or a purge gas. A series of injector holes 132 is provided in the injector wall 128. The holes 132 are spaced apart between the upper injector end 130 and the lower injector end 129. A gas entering the injector 127 through a gas input 131 travels through the gas conduit and exits the injector through the injector holes 132.

The injector wall 128 comprises a bend 133 between the upper injector end 130 and the lower injector end 129. The bend 133 may be S-shaped. The bend 133 may be provided below a lowest of the injector holes 132. The bend 133 may be provided between the injector holes 132 and the lower injector end 129.

By providing the injector 127 having a bend 133 together with the liner 101, an assembly of a liner and injector may be provided in which the injector may conform to an inner shape of the liner when accommodated in a bulge of the liner. This may allow for the liner diameter to be reduced at the first liner section 110 so as to decrease the annular volume, while still providing space for the injector to be accommodated and to be installed/removed.

The injector holes 132 may be positioned so as to allow gas to flow out from the gas conduit through the holes in a direction which is substantially tangential to the inner surface 107 of the liner in a plane perpendicular to the longitudinal direction. This may allow for a reduction in particle contamination of wafers by particles which may be carried by a gas exiting the injector 127. The injector holes 132 may be positioned so as to allow gas to flow out from the gas conduit through the holes in a direction which is substantially perpendicular to the inner surface 107 of the liner in a plane perpendicular to the longitudinal axis of the liner. This may allow for a more uniform distribution of gas in a space between wafers.

The injector 127 may comprise a plurality of projections 134 at the upper injector end 130. When provided in a liner 101 as an assembly of an injector and a liner, in embodiments where the liner 101 comprises a second through hole 122, a process gas may be deposited in the second through hole 122 in a space between the upper injector end 130 and the liner wall 105 and/or in a space between the upper injector end 130 and a second cap 124. This may cause the injector 127 to be attached to the liner wall 105 and/or the cap 124 and may make removal of the injector 127 challenging due to increased likelihood of particle generation and damage to the injector 127. By providing the projections 134, contact area between the upper injector end 130 and the liner wall/second cap may be reduced so as to reduce the chance of the upper injector end 130 becoming attached.

Referring to FIG. 14, an assembly of an injector 127 and a liner 101 according to embodiments of the present invention is shown in a batch semiconductor processing apparatus 135. The semiconductor processing apparatus 135 comprises a process chamber 136 which is generally bell jar shaped, having a closed top end 137, a closable bottom end 138, and an interior space 139. The semiconductor processing apparatus 135 may be a vertical furnace and the process chamber 136 may accordingly extend in a vertical direction between the top end 137 and the bottom end 138. The semiconductor processing apparatus 135 may comprise a flange 140 for at least partially supporting the process chamber 136 at the bottom end 138. The flange 140 may be generally circular in shape as viewed along the vertical direction. The flange 140 may be configured to partially close off the bottom end 138 of the process chamber 136. The flange 140 may support the liner 101 according to embodiments of the present invention.

The semiconductor processing apparatus 135 may comprise a heater (not shown) for heating the process chamber 136 and thereby heating the interior space. The flange 140 may comprise a gas inlet 145 to which a gas input 131 of the injector 127 may be connected so as to provide a gas to the injector 127. The injector 127 is provided in the second bulge 118 of the liner 101. The injector 127 may be configured such that when provided in the liner 101, the bend 133 of the injector 127 is not precisely aligned with the transition section 112 of the liner 101. This may allow for greater freedom of movement in installation and removal of the injector 127. If the bend 133 is located below the transition section 112, the injector 127 can be moved upwards during installation/removal without causing collision of the bend 133 with the transition section 112 of the liner 101.

A thermocouple 146 or other component extending in the longitudinal direction may be provided in the first bulge 117 of the liner 101. The flange 140 may comprise a gas outlet (not shown) which may be connected to a vacuum pump for removing a gas from the interior space 139.

The semiconductor processing apparatus 135 comprises a doorplate 141 configured to at least partially close off the bottom end 138 of the process chamber 136. The doorplate 141 may support a pedestal 142 thereon. The pedestal 142 may be configured to support a substrate carrier or boat 143. The pedestal 142 and boat 143 may be inserted into and removed from the process chamber 136 through the bottom end 138 by moving the doorplate 141 in a vertical direction.

The boat 143 is configured to support a plurality of substrates 144 therein. The plurality of substrates 144 may be spaced apart in a vertical direction. The boat 143 may comprise two end plates spaced apart by a plurality of support rods. The plurality of support rods may comprise a plurality of sets of slots or projections for supporting the plurality of substrates, each set of slots or projections being spaced apart from the other sets of slots or projections in the vertical direction. Each set of slots or projections being at a same vertical position forms a respective substrate receiving position. The liner 101 is arranged in the interior space 139 so that the boat 143 is positioned within the liner 101.

An annular volume 147 is formed between the edges of the substrates and the inner surface 107 of the liner 101. The liner 101 according to embodiments of the present invention provides a decreased annular volume 147 when provided in the process chamber 136, which may contribute to improved uniformity of deposition on a substrate provided in the boat 143.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A liner for a process chamber of a batch semiconductor processing apparatus, the liner comprising:
a closed upper end;
an open lower end adapted for receiving a substrate boat; and
a plurality of exhaust openings in the liner, distributed between the upper end and the lower end;
wherein the liner has a first diameter in a first liner section adjacent to the upper end and a second diameter in a second liner section adjacent to the lower end, wherein the liner diameter increases continuously from the first diameter to the second diameter in a transition section between the first section and the second section.

2. The liner of claim 1, wherein the transition section has a height of at least 30 mm.

3. The liner of claim 1, wherein the first liner section has a height of at least three times a height of the second liner section.

4. The liner of any one of claim 1, wherein the second diameter is at least 1.1 times the first diameter.

5. The liner of any one of claim 1, wherein the plurality of exhaust openings includes at least one opening in the transition section and at least one opening in the second liner section.

6. The liner of any one of claim 1, wherein the plurality of exhaust openings comprises a plurality of holes.

7. The liner of any one of claim 1, wherein the plurality of exhaust openings comprises a plurality of slits, each slit extending in a circumferential direction.

8. The liner of any one of claim 1, wherein the plurality of exhaust openings comprises a first series of openings located at a first circumferential position and spaced apart along a longitudinal axis of the liner, and a second series of openings located at a second, different circumferential position and spaced apart along a longitudinal axis of the liner.

9. The liner of claim 8, wherein the liner comprises a first bulge extending along the longitudinal axis and located between the first series of openings and the second series of openings.

10. The liner of claim 9, comprising a hole in the upper end of the liner at a top end of the first bulge.

11. The liner of claim 9, wherein the liner comprises a second bulge extending along a longitudinal axis of the liner, located substantially diametrically opposite to the first bulge.

12. The liner of claim 11, comprising a hole in the upper end of the liner at a top end of the second bulge.

13. An assembly of the liner of claim 11 and a gas injector receivable in the second bulge, wherein the gas injector comprises:
a lower injector end and an upper injector end;
an injector wall extending between the lower injector end and the upper injector end and defining a gas conduit; and
a series of holes in the injector wall spaced apart between the lower injector end and the upper injector end;
wherein the injector wall comprises a bend configured to allow the injector to conform to a shape of the liner when the injector is accommodated in the second bulge of the liner.

14. The assembly of claim 13, wherein the bend is an S-shaped bend.

15. The assembly of claim 13, wherein the bend is provided between a lowest of the series of holes and the lower injector end.

16. The assembly of claim 13, wherein no holes are provided in the injector wall at a position of the bend.

17. The assembly of claim 13, wherein the holes in the injector wall are positioned so as to allow gas to flow out from the gas conduit through the holes in a direction which is substantially tangential to the liner in a plane perpendicular to the longitudinal axis of the liner.

18. The assembly of claim 13, wherein the holes in the injector wall are positioned so as to allow gas to flow out from the gas conduit through the holes in a direction which is substantially perpendicular to the liner in a plane perpendicular to the longitudinal axis of the liner.

19. The assembly of claim 12, wherein the injector comprises a plurality of projections at the upper injector end.

20. The assembly of claim 13, comprising a cap configured to close off a hole in the upper end of the liner at a top end of the second bulge.
